(19) United States
(12) Patent Application Publication
(10) Pub. No.: US 2024/0006293 A1
(43) Pub. Date: Jan. 4, 2024

(54) SEMICONDUCTOR PACKAGE

(71) Applicant: SAMSUNG ELECTRONICS CO., LTD., SUWON-SI (KR)

(72) Inventor: Seon HEO, Suwon-si (KR)

(21) Appl. No.: 18/143,735

(22) Filed: May 5, 2023

(30) Foreign Application Priority Data
Jul. 4, 2022 (KR) 10-2022-0081758

(51) Int. Cl. H01L 23/498

(52) U.S. Cl. CPC H01L 23/49838; H01L 23/49816; H01L 23/49822; H01L 25/105

(57) ABSTRACT

A semiconductor package includes: a package substrate including a first region, a second region, a first surface, and a second surface opposing the first surface; a semiconductor chip mounted on the package substrate; a pad including a first sub-pad, which is disposed on the second surface of the first region, and a second sub-pad, which is disposed on the second surface of the second region and includes a solder ball recess; and a solder ball disposed on the second surface, wherein the solder ball includes a first sub-solder ball and a second sub-solder ball, wherein the first sub-solder ball is connected to the first sub-pad, and the second sub-solder ball is connected to the second sub-pad, wherein the second sub-solder ball includes a first portion and a second portion, wherein the first portion is disposed in the solder ball recess, and the second portion is disposed on the first portion.

### CROSS-REFERENCE TO RELATED APPLICATION

This application claims priority under 35 U.S.C. 119(a) to Korean Patent Application No. 10-2022-0081758 filed on Jul. 4, 2022 in the Korean Intellectual Property Office, the disclosure of which is incorporated by reference herein in its entirety.

### TECHNICAL FIELD

The present inventive concept relates to a semiconductor package, and more particularly, to a semiconductor package including a package substrate and an outermost pad that includes a hole and is on the package substrate.

### DISCUSSION OF THE RELATED ART

A semiconductor package implements an integrated circuit chip for use in electronic products. Typically, a semiconductor package is configured such that a semiconductor chip is mounted on a printed circuit board (PCB), and bonding wires or bumps are used to electrically connect the semiconductor chip to the printed circuit board. With the development of electronic industry, semiconductor packages with increased reliability and miniaturization have been under development.

When a pad, to which a semiconductor package and an external board are connected, is formed flat without being bent, cracks that occur in the pad are likely to further develop and increase in size, and thus, the performance and reliability of the semiconductor package may deteriorate.

### SUMMARY

Aspects of the present inventive concept provide a semiconductor package capable of increasing reliability of a product.

However, aspects of the present inventive concept are not restricted to those set forth herein. The above and other aspects of the present inventive concept will become more apparent to one of ordinary skill in the art to which the present inventive concept pertains by referencing the detailed description of the present inventive concept given below.

According to an exemplary embodiment of the present inventive concept, a semiconductor package includes; a package substrate including a first region and a second region excluding the first region, wherein the package substrate includes a first surface and a second surface that are opposed to each other; a semiconductor chip mounted on the first surface of the package substrate; a pad including a first sub-pad and a second sub-pad, wherein the first sub-pad is disposed on the second surface of the first region of the package substrate, and the second sub-pad is disposed on the second surface of the second region of the package substrate and includes a solder ball recess; and a solder ball disposed on the second surface, wherein the solder ball includes a first sub-solder ball and a second sub-solder ball, wherein the first sub-solder ball is connected to the first sub-pad, and the second sub-solder ball is connected to the second sub-pad, wherein the second sub-solder ball includes a first portion and a second portion, wherein the first portion is disposed in the solder ball recess, and the second portion is disposed on the first portion.

According to an exemplary embodiment of the present inventive concept, a semiconductor package includes: a package substrate including an edge region and a central region excluding the edge region, wherein the package substrate includes a first surface and a second surface that are opposed to each other; a semiconductor chip mounted on the central region of the package substrate; a first sub-redistribution pattern disposed at the central region of the package substrate; a second sub-redistribution pattern disposed at the edge region of the package substrate and including a trench; a first sub-pad disposed on the second surface of the package substrate and connected to the first sub-redistribution pattern; a second sub-pad disposed on the second surface of the package substrate and connected to the second sub-redistribution pattern; a first sub-solder ball connected to the first sub-pad; and a second sub-solder ball connected to the second sub-pad, wherein the second sub-pad extends along a sidewall and a bottom surface of the trench, wherein at least a part of the second sub-solder ball is disposed on second sub-pad in the trench, wherein the at least a part of the second sub-solder ball overlaps the second sub-redistribution pattern in a direction that is substantially perpendicular to a thickness direction of the package substrate, and wherein an upper surface of the first sub-pad is flat.

According to an exemplary embodiment of the present inventive concept, a semiconductor package includes: a package substrate including four edge regions and a central region excluding the edge regions, wherein the package substrate includes a first surface and a second surface that are opposed to each other, wherein each of the four edge regions having a step shape; at least one semiconductor chip mounted on the first surface of the central region of the package substrate; a solder resist layer disposed on the second surface and including a first trench; a redistribution pattern including a first sub-redistribution pattern and a second sub-redistribution pattern, wherein the first sub-redistribution pattern is disposed at the central region of the package substrate, and the second sub-redistribution pattern is disposed at the edge region of the package substrate and includes a plurality of second trenches; a first sub-pad extending along a bottom surface of the first trench and being connected to the first sub-redistribution pattern; a second sub-pad extending along the bottom surface of the first trench and a sidewall and a bottom surface of the second trench and being connected to the second sub-redistribution pattern; a first sub-solder ball connected to the first sub-pad; and a second sub-solder ball connected to the second sub-pad, wherein the first trench exposes the redistribution pattern, wherein the plurality of second trenches do not expose the package substrate, wherein the second sub-solder ball includes a first portion and a second portion, wherein the first portion fills the second trenches, and the second portion is disposed on the first portion, wherein the first portion of the second sub-solder ball does not overlap the first sub-solder ball in a direction that is substantially perpendicular to a thickness direction of the package substrate, and wherein each of the first sub-pad and the second sub-pad includes NiAu.

### BRIEF DESCRIPTION OF THE DRAWINGS

The above and features of the present inventive concept will become more apparent by describing in detail exemplary embodiments thereof with reference to the attached drawings, in which:

FIG. 1 is a schematic plan view of a semiconductor package according to an exemplary embodiment of the present inventive concept.

FIG. 2 is a cross-sectional view taken along line A-A of FIG. 1.

FIG. 3 is an enlarged view of portion P2 of FIG. 2.

FIG. 4 is an enlarged view of portion P1 of FIG. 1.

FIGS. 5, 6 and 7 are plan views of a semiconductor package according to an exemplary embodiment of the present inventive concept.

FIGS. 8,9 and 10 are enlarged views of a semiconductor package according to an exemplary embodiment of the present inventive concept.

FIGS. 11, 12, 13 and 14 are enlarged views of a semiconductor package according to an exemplary embodiment of the present inventive concept.

FIGS. 15, 16, and 17 are cross-sectional views of a semiconductor package according to an exemplary embodiment of the present inventive concept.

FIG. 18 is a plan view of a semiconductor package according to an exemplary embodiment of the present inventive concept.

FIG. 19 is a cross-sectional view taken along line B-B of FIG. 18.

FIGS. 20, 21, 22, 23, and 24 are views illustrating intermediate stages of a method of manufacturing a semiconductor package according to an exemplary embodiment of the present inventive concept.

### DETAILED DESCRIPTION OF THE EMBODIMENTS

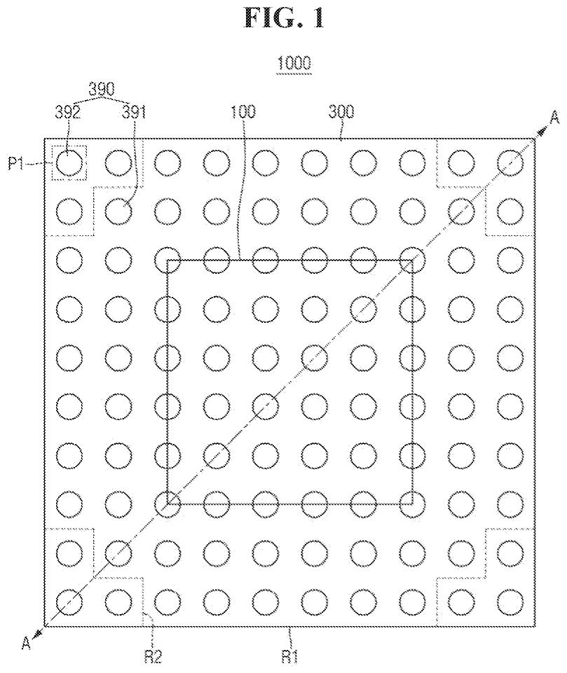

Hereinafter, a semiconductor package according to an exemplary embodiment of the present inventive concept will be described with reference to FIGS. 1 to 19.

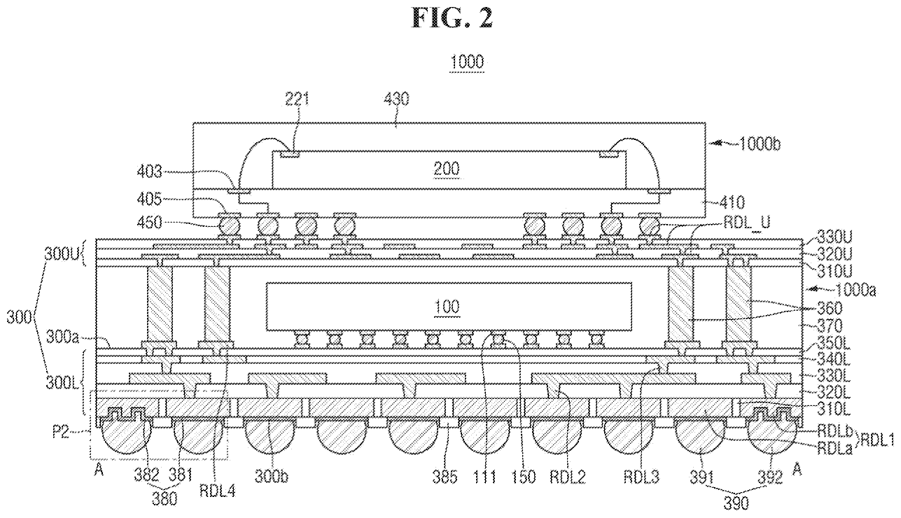

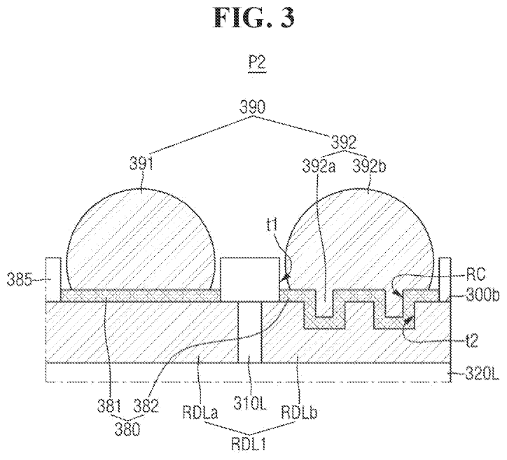

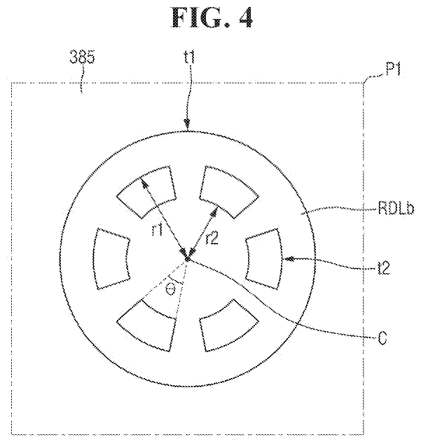

FIG. 1 is a schematic plan view of a semiconductor package according to an exemplary embodiment of the present inventive concept. FIG. 2 is a cross-sectional view taken along line A-A of FIG. 1. FIG. 3 is an enlarged view of portion P2 of FIG. 2. FIG. 4 is an enlarged view of portion P1 of FIG. 1.

Referring to FIGS. 1 and 2, a semiconductor package 1000 according to an exemplary embodiment of the present inventive concept may include a first semiconductor package 1000a and a second semiconductor package 1000b provided on the first semiconductor package 1000a.

The first semiconductor package 1000a may include a package substrate 300, a first semiconductor chip 100, and a solder resist layer 385, a solder ball 390, and a pad 380.

The package substrate 300 may include a lower package substrate 300L and an upper package substrate 300U. The first semiconductor chip 100 may be disposed between the lower package substrate 300L and the upper package substrate 300U. The lower package substrate 300L may be disposed under the first semiconductor chip 100. The upper package substrate 300U may be disposed above the first semiconductor chip 100. For example, the lower package substrate 300L may include a first surface 300a and a second surface 300b opposed to the first surface 300a. The upper package substrate 300U and the first semiconductor chip 100 may be disposed on the lower package substrate 300L and the first surface 300a. The solder ball 390 may be disposed on the second surface 300b of the lower package substrate 300L.

In FIG. 1, the package substrate 300 may include a first region R1 and a second region R2 excluding the first region R1. The first region R1 may be a central region and the second region R2 may be an edge region. For example, when the package substrate 300 has a quadrilateral shape in a plan view, the second region R2 may be a corner portion of the quadrilateral shape. The first region R1 may be the remaining region other than the second region R2. For example, four second regions R2 may be provided, but the present inventive concept is not limited thereto. For example, the first region R1 may be between the second region R2.

In an exemplary embodiment of the present inventive concept, the second region R2 may have a step shape in a plan view. In this specification, when the second region “has a step shape in a plan view,” a boundary line between the second region R2 and the first region R1 may have a step shape. In addition, when the second region “has a step shape in a plan view,” the solder balls 390 disposed in the second region R2 may be disposed in a step shape in a plan view. For example, second sub-solder balls 392, which will be described below, may be disposed in the second region R2 in a step shape, but the present inventive concept is not limited thereto.

The first semiconductor chip 100 may be provided on the first region R1. The first semiconductor chip 100 may be mounted on the first surface 300a of the lower package substrate 300L. The first semiconductor chip 100 may overlap the first region R1 in a thickness direction of the package substrate 300 or in a direction substantially perpendicular to the first surface 300a of the lower package substrate 300L. For example, an entirety of the first semiconductor chip 100 may overlap the first region R1. The first semiconductor chip 100 might not completely overlap the second region R2 in the thickness direction of the package substrate 300. However, the present inventive concept might not be limited thereto.

The lower package substrate 300L may include the first surface 300a and the second surface 300b. The first surface 300a and the second surface 300b may be opposed to each other. The first surface 300a may face the first semiconductor chip 100. The second surface 300b may face the solder ball 390.

In an exemplary embodiment of the present inventive concept, the lower package substrate 300L may include first to fifth lower dielectric layers 310L, 320L, 330L, 340L, and 350L. First to fourth redistribution patterns RDL1, RDL2, RDL3, and RDL4 may be disposed within the first to fifth lower dielectric layers 310L, 320L, 330L, 340L, and 350L.

For example, the first lower dielectric layer 310L may at least partially surround the first redistribution pattern RDL1. The second lower dielectric layer 320L may at least partially surround a via part of the second redistribution pattern RDL2. The third lower dielectric layer 330L may at least partially surround a line part of the second redistribution pattern RDL2 and a via part of the third redistribution pattern RDL3. The fourth lower dielectric layer 340L may at least partially surround a line part of the third redistribution pattern RLD3. The fifth lower dielectric layer 350L may at least partially surround a via part of the fourth redistribution pattern RDL4. However, the present inventive concept might not be limited thereto.

Each of the first to fifth lower dielectric layers 310L, 320L, 330L, 340L, and 350L may be formed of a photo-imageable dielectric (PID). For example, the first to fifth lower dielectric layers 310L, 320L, 330L, 340L, and 350L may include a photosensitive polymer. The photosensitive polymer may include, for example, one or more of photosensitive polyimide, polybenzoxazole, phenolic polymers, and/or benzocyclobutene polymers. In another example, the first to fifth lower dielectric layers 10 may be formed of a silicon oxide layer, a silicon nitride layer, and/or a silicon oxynitride layer.

The first to fourth redistribution patterns RDL1, RDL2, RDL3, and RDL4 may include a conductive material. For example, the first to fourth redistribution patterns RDL1, RDL2, RDL3, and RDL4 may include copper (Cu), but the present inventive concept is not limited thereto.

In an exemplary embodiment of the present inventive concept, the lower package substrate 300L may include an organic material. For example, the lower package substrate 300L may include pre-preg. The pre-preg is a composite fiber obtained by impregnating reinforcing fibers such as carbon fiber, glass fiber, and aramid fiber with a thermosetting polymer binder (e.g., epoxy resin) and/or a thermoplastic resin. In an exemplary embodiment of the present inventive concept, the lower package substrate 300L may include a copper clad laminate (CCL). For example, the lower package substrate 300L may have a structure in which a copper laminate is stacked on one side or both sides of a thermosetting pre-preg (for example, pre-preg of a C-Stage).

In an exemplary embodiment of the present inventive concept, the first redistribution pattern RDL1 may include a first sub-redistribution pattern RDLa and a second sub-redistribution pattern RDLb. The first sub-redistribution pattern RDLa may be disposed in the first region R1 of the package substrate 300. The second sub-redistribution pattern RDLb may be disposed in the second region R2 of the package substrate 300. For example, the first sub-redistribution pattern RDLa may be disposed in the central region, and the second sub-redistribution pattern RDLb may be disposed in the edge region. For example, the first sub-redistribution pattern RDLa may be at least partially surrounded by the second sub-redistribution pattern RDLb.

The pad 380 may be disposed on the first redistribution pattern RDL1. The pad 380 may be disposed on the second surface 300b. The pad 380 may be connected to the first redistribution pattern RDL1. In an exemplary embodiment of the present inventive concept, the pad 380 may include a first sub-pad 381 and a second sub-pad 382. The first sub-pad 381 may be disposed in the first region R1. The second sub-pad 382 may be disposed in the second region R2. The first sub-pad 381 may be disposed in the central region of the package substrate. The second sub-pad 382 may be disposed in the edge region of the package substrate. The first sub-pad 381 may be connected to the first sub-redistribution pattern RDLa. The second sub-pad 382 may be connected to the second sub-redistribution pattern RDLb. For example, the second sub-pad 382 may at least partially surround the first sub-pad 381. The pad 380 may include, for example, NiAu, but is not limited thereto.

The solder ball 390 may be provided on the pad 380. The solder ball 390 may be connected to the pad 380. In an exemplary embodiment of the present inventive concept, the solder ball 390 may include a first sub-solder ball 391 and a second sub-solder ball 392. The first sub-solder ball 391 may be provided on the first region R1. The second sub-solder ball 392 may be provided on the second region R2. The first sub-solder ball 391 may be provided on the central region of the package substrate 300. The second sub-solder ball 392 may be provided on the edge region of the package substrate 300. For example, the second sub-solder ball 392 may at least partially surround the first sub-solder ball 391.

The first sub-solder ball 391 may be connected to the first sub-pad 381. The second sub-solder ball 392 may be connected to the second sub-pad 382. Although the solder ball 390 is illustrated as having a ball shape, the present inventive concept is not limited thereto. The solder ball 390 may have various shapes, such as a land, a ball, a pin, and/or a pillar. The number, interval, arrangement form, and the like of the solder ball 390 are not limited to those shown and may of course be various. The solder ball 390 may be, for example, but is not limited to, a solder bump. The solder bump may include, for example, a metal (e.g., tin (Sn)) and/or a Sn alloy with a low-melting point.

The solder resist layer 385 may be disposed on the second surface 300b. The solder resist layer 385 may be disposed on the first redistribution pattern RDL1 and the first lower dielectric layer 310L. The solder resist layer 385 may include a solder resist material.

Hereinafter, the solder ball 390, the pad 380, the first redistribution pattern RDL1, and the solder resist layer 385 will be described with reference to FIG. 3. FIG. 3 is an enlarged view of portion P2 of FIG. 2.

Referring to FIG. 3, the first redistribution pattern RDL1 includes the first sub-redistribution pattern RDLa and the second sub-redistribution pattern RDLb. The pad 380 includes the first sub-pad 381 and the second sub-pad 382. The solder ball 390 includes the first sub-solder ball 391 and the second sub-solder ball 392.

In an exemplary embodiment of the present inventive concept, the second sub-redistribution pattern RDLb may include a second trench t2. The second trench t2 might not expose the lower package substrate 300L. The second trench t2 may expose the second sub-redistribution pattern RDLb. The first sub-redistribution pattern RDLa does not include the second trench 2. For example, an upper surface of the first sub-redistribution pattern RDLa is flat. In addition, an upper surface of the second sub-redistribution pattern RDLb is not flat. The upper surface of the first sub-redistribution pattern RDLa may be substantially coplanar with the second surface 300b.

The first sub-pad 381 may be disposed along the upper surface of the first sub-redistribution pattern RDLa. Accordingly, an upper surface of the sub-pad 381 may be flat. The second sub-pad 382 may be disposed along the upper surface of the second sub-redistribution pattern RDLb. The second sub-pad 382 may be disposed along a sidewall and a bottom surface of the second trench t2. A bottom surface of the first trench t1 may be opposed to the first surface 300a. A bottom surface of the second trench t2 may be opposed to the first surface 300a. The bottom surface of the second trench t2 may face the second sub-solder ball 392. The second sub-pad 382 may form a solder ball recess RC. The solder ball recess RC may include the region of the second trench t2 remaining after the second sub-pad 382 is formed.

In an exemplary embodiment of the present inventive concept, the pad 380 may have a substantially constant thickness. A thickness of the first sub-pad 381 might not be constant. A thickness of the second sub-pad 382 may be substantially constant. The pad 380 may be conformally formed on the first redistribution pattern RDL1. However, the present inventive concept might not be limited thereto.

The solder resist layer 385 may include the first trench t1. The first trench t1 may expose the first redistribution pattern RDL1. The pad 380 and the solder ball 390 may be disposed in the first trench t1. The first sub-pad 381 may extend along the bottom surface of the first trench t1. The second sub-pad 382 may extend along the bottom surface of the first trench t1, the sidewall of the second trench t2, and the bottom surface of the second trench t2.

The solder ball 390 may be provided on the pad 380. The first sub-solder ball 391 may be disposed on the first sub-pad 381. The first sub-solder ball 391 may be connected to the first sub-pad 381. The second sub-solder ball 392 is disposed on the second sub-pad 382. The second sub-solder ball 392 is connected to the second sub-pad 382. In an exemplary embodiment of the present inventive concept, at least a portion of the second sub-solder ball 392 may be disposed in the solder ball recess RC. At least a portion of the second sub-solder ball 392 may be disposed in the second trench t2.

In an exemplary embodiment of the present inventive concept, the second sub-solder ball 392 may include a first portion 392a and a second portion 392b. The first portion 392a of the second sub-solder ball 392 may be disposed in the solder ball recess RC. The first portion 392a of the second sub-solder ball 392 may be disposed in the second trench t2. The second portion 392b of the second sub solder ball 392 may be disposed on the first portion 391b.

The second sub-solder ball 392 has a structure in which its portion is disposed in the solder ball recess RC, so that a contact area between the second sub-solder ball 392 and the second sub-pad 382 may be increased. Accordingly, when a crack is generated, the crack may be prevented from developing (e.g., increasing in size). Thus, a semiconductor package having increased reliability may be provided.

A part of the first portion 392a of the second sub-solder ball 392 may overlap the second sub-redistribution pattern RDLb in a first direction. The first direction may be substantially perpendicular to the thickness direction of the package substrate 300. A part of the first portion 392a of the second sub-solder ball 392 may overlap the first sub-redistribution pattern RDLa in the first direction. The first portion 392a of the second sub-solder ball 392 does not completely overlap the first sub-solder ball 391 in the first direction. The first sub-solder ball 391 does not overlap the first sub-redistribution pattern RDLa in the first direction. The first sub-solder ball 391 does not overlap the second sub-redistribution pattern RDLb in the first direction. However, the present inventive concept might not be limited thereto.

Hereinafter, the first trench t1 and the second trench t2 according to an exemplary embodiment of the present inventive concept will be described in more detail with reference to FIG. 4. FIG. 4 is an enlarged view of portion P1 of FIG. 1. For convenience of illustration, FIG. 4 omits the second sub-solder ball 392 and the second sub-pad 382.

Referring to FIG. 4, the second trench t2 may be formed in the first trench t1. In a plan view, the shape of the second trench t2 may be a part of a fan shape. For example, the shape of the second trench t2 in a plan view may be a shape obtained by removing a second fan shape having a second radius r2 from a first fan shape having a first radius r1. In this case, a central angle θ of the first fan shape may be the same as a central angle θ of the second fan shape. The first radius r1 may be greater than the second radius r2. However, the present inventive concept might not be limited thereto. For example, the second trench t2 may have a rounded shape.

In an exemplary embodiment of the present inventive concept, the second trench t2 might not be formed in the central region of the first trench t1. For example, the second trench t2 might not be formed in the center C of the first trench t1, but the present inventive concept is not limited thereto.

Although six second trenches t2 are shown in FIG. 4, the present inventive concept is not limited thereto. The number, shape arrangement, and the like of the second trench t2 may, of course, vary.

Referring back to FIG. 2, the semiconductor package 1000 according to an exemplary embodiment of the present inventive concept may further include a plurality of metal pillars 360, a molding layer 370, a plurality of first chip pads 111, and a plurality of first connection terminals 150.

The first chip pads 111 may be provided on a lower surface of the first semiconductor chip 100. The lower surface of the first semiconductor chip 100 may be disposed to face the first surface 300a of the lower package substrate 300L. The first chip pads 111 of the first semiconductor chip 100 may be connected to the fourth redistribution pattern RDL4.

The first connection terminals 150 may be attached between the first chip pads 111 of the first semiconductor chip 100 and an underlying fourth redistribution pattern RDL4. Through the first connection terminals 150, the first semiconductor chip 100 and the solder ball 390 may be electrically connected to each other. The first connection terminals 150 may be, for example, but are not limited to, a solder bump. The solder bump may include, for example, a metal (e.g., tin (Sn)) and/or a Sn alloy with a low-melting point. The first connection terminals 150 may have various shapes, such as a land, a ball, a pin, and/or a pillar. The first connection terminals 150 may each be formed of a single layer or multi-layers. When the first connection terminals 150 are each formed of a single layer, the first connection terminals 150 may include, for example, tin-silver (Sn—Ag) solder and/or copper (Cu). When the first connection terminals 150 are each formed of multi-layers, the first connection terminals 150 may include, for example, a copper filler and solder. The number, interval, arrangement form, and the like of the first connection terminals 150 are not limited to those shown, and may, of course, be various.

The metal pillars 360 may be provided around the first semiconductor chip 100. The metal pillars 360 may electrically connect the lower package substrate 300L to the upper package substrate 300U. The metal pillars 360 may penetrate the molding layer 370. Upper surfaces of the metal pillars 360 may be substantially coplanar with an upper surface of the molding layer 370. Lower surfaces of the metal pillars 360 may be in contact with the fourth redistribution pattern RDL4 of the lower package substrate 300L.

The molding layer 370 may be provided between the lower package substrate 300L and the upper package substrate 300U. The molding layer 370 may cover the first semiconductor chip 100. The molding layer 370 may be provided on the first surface 300a of the lower package substrate 300L. The molding layer 370 may cover a sidewall and an upper surface of the first semiconductor chip 100. The molding layer 370 may fill gaps between the metal pillars 360 and between the first semiconductor chip 100 and the metal pillars 360. The thickness of the molding layer 370 may be substantially the same as the thickness of each of the metal pillars 360. The molding layer 370 may include a dielectric polymer, such as an epoxy-based molding compound.

The upper package substrate 300U may include first to third upper dielectric layers 310U, 320U, and 330U and upper redistribution patterns RDL_U in the first to third upper dielectric layers 310U, 320U, and 330U. The first to third upper dielectric layers 310U, 320U, and 330U may have the same material as the material included in the first to fifth lower dielectric layers 310L, 320L, 330L, 340L, and 350L. The upper redistribution patterns RDL_U may include the same material as that of the first to fourth redistribution patterns RDL1, RDL2, RDL3, and RDL4.

The second semiconductor package 1000b may be disposed on the upper package substrate 300U. The second semiconductor package 1000b may include a circuit board 410, a second semiconductor chip 200, and an upper molding layer 430. The circuit board 410 may be a printed circuit board (PCB), but is not limited thereto. A lower conductive pad 405 may be disposed on a lower surface of the circuit board 410.

The second semiconductor chip 200 may be disposed on the circuit board 410. The second semiconductor chip 200 may include integrated circuits. The integrated circuits may include, for example, a memory circuit, a logic circuit, or a combination thereof. The second semiconductor chip 200 may include second chip pads 221 electrically connected to upper conductive pads 403 on an upper surface of the circuit board 410 through wire bonding. The upper conductive pad 403 on the upper surface of the circuit board 410 may be electrically connected to a lower conductive pad 405 through an internal wiring line in the circuit board 410.

The upper molding layer 430 may be provided on the circuit board 410. The upper molding layer 430 may cover the second semiconductor chip 200. The upper molding layer 430 may include a dielectric polymer, such as an epoxy-based polymer.

The semiconductor package 1000 according to an exemplary embodiment of the present inventive concept may further include a plurality of second connection terminals 450. The second connection terminals 450 may be provided between the lower conductive pads 405 of the circuit board 410 and the upper redistribution patterns RDL_U. The second connection terminals 450 may be, for example, but is not limited to, a solder bump. The solder bump may include, for example, a metal (e.g., tin (Sn)) and/or a Sn alloy with a low-melting point. The second connection terminals 450 may have various shapes, such as a land, a ball, a pin, and/or a pillar. The second connection terminals 450 may each be formed of a single layer or multi-layers. When the second connection terminals 450 are each formed of a single layer, the second connection terminals 450 may include, for example, tin-silver (Sn—Ag) solder and/or copper (Cu). When the second connection terminals 450 are each formed of multi-layers, the second connection terminals 450 may include, for example, a copper filler and solder. The number, interval, arrangement form, and the like of the second connection terminals 450 are not limited to those shown, and may, of course, be various.

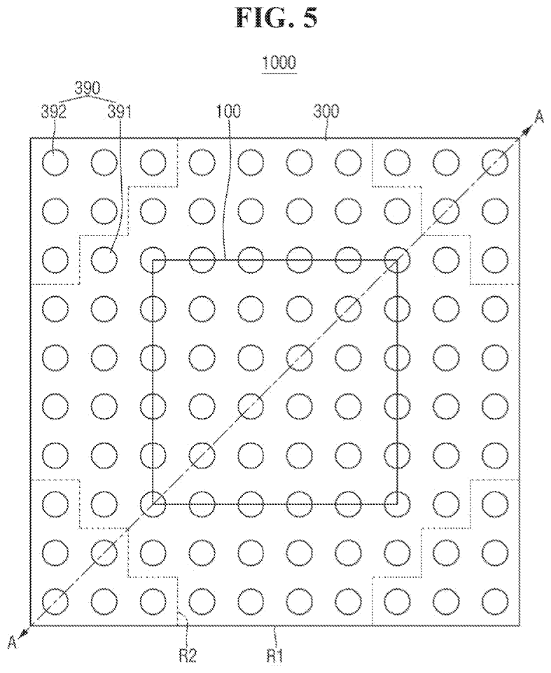

FIGS. 5 to 7 are plan views of a semiconductor package according to an exemplary embodiment of the present inventive concept. Hereinafter, various exemplary embodiments of a semiconductor package will be described with reference to FIGS. 5 to 7.

Referring to FIG. 5, a second region R2 may have a three-step shape in a plan view. For example, the area of the second region R2 may be increased. For example, six second sub-solder balls 392 may be disposed in the second region R2. As the area of the second region R2 increases, when a crack is generated, developing of the crack may be more efficiently prevented. In addition, as the number of second sub-solder balls 392 in the second region R2 increases, when a crack is generated, developing of the crack may be more efficiently prevented.

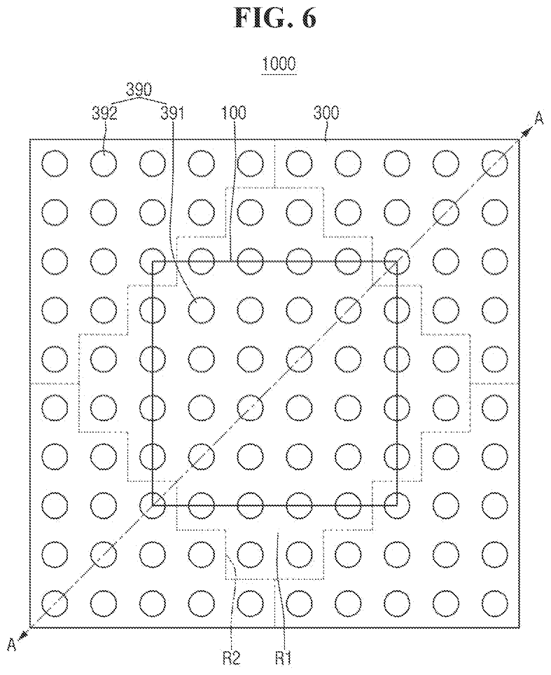

Referring to FIG. 6, the second region R2 may have a five-step shape in a plan view. For example, the area of the second region R2 may be further increased. In addition, the second region R2 may include a region that overlaps the first semiconductor chip 100 in a thickness direction of the package substrate 300. Some of the second sub-solder balls 392 may overlap the first semiconductor chip 100 in the thickness direction of the package substrate 300.

In an exemplary embodiment of the present inventive concept, a part of the boundary line of the second region R2 may be in contact with the boundary line of an adjacent second region R2. However, the present inventive concept might not be limited thereto.

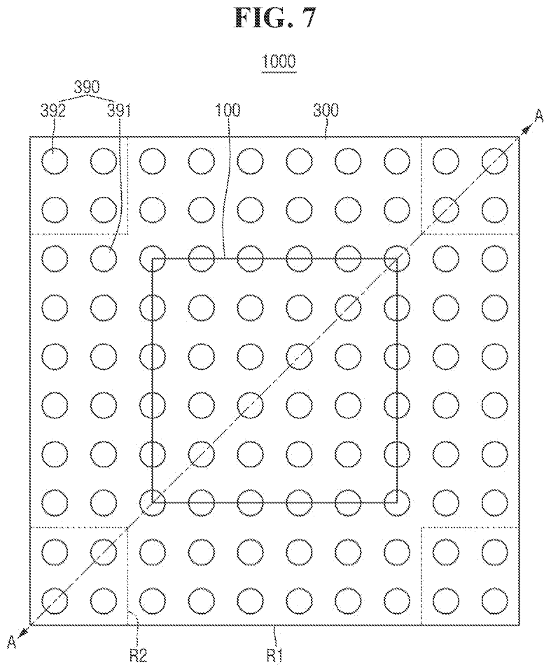

Referring to FIG. 7, the second region R2 might not have a step shape in a plan view. In one example, the second region R2 may have a square shape in a plan view; however, the present inventive concept is not limited thereto, and for example, the second region R2 may have a different polygonal shape. The second region R2 may have a rectangular shape in a plan view. The second region R2 does not overlap the first semiconductor chip 100 in the thickness direction of the package substrate 300.

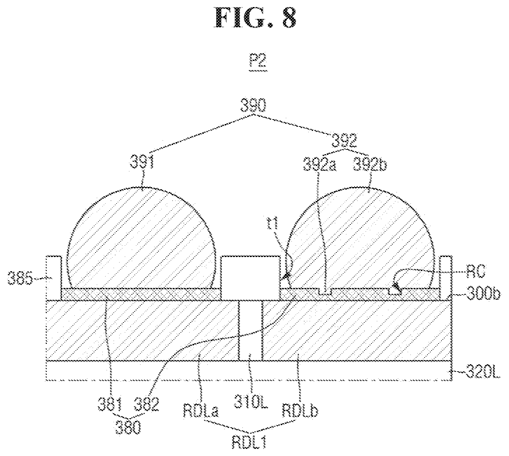

FIGS. 8 to 10 are enlarged views of a semiconductor package according to an exemplary embodiment of the present inventive concept. Hereinafter, various embodiments of a semiconductor package will be described with reference to FIGS. 8 to 10.

Referring to FIG. 8, the second sub-redistribution pattern RDLb does not include the second trench t2.

The solder ball recess RC may be formed in the second sub-pad 382. The solder ball recess RC does not expose the second sub-redistribution pattern RDLb. The first portion 392a of the second sub-solder ball 392 is disposed in the solder ball recess RC. The first portion 392a of the second sub-solder ball 392 does not overlap the first sub-pad 381 in the first direction. The first direction may be substantially perpendicular to the thickness direction of a package substrate. The first portion 392a of the second sub-solder ball 392 overlaps the second sub-pad 382 in the first direction.

In an exemplary embodiment of the present inventive concept, the second sub-pad 382 might not have a constant thickness. The thickness of the second sub-pad 382 at the portion where the solder ball recess RC is formed may be smaller than the thickness of the second sub-pad 382 at the portion where the solder ball recess RC is not formed.

Referring to FIG. 9, the second trench t2 may expose the second sub-redistribution pattern RDLb and the second lower dielectric layer 320L. The second trench t2 may expose the lower package substrate (300L in FIG. 2). However, the present inventive concept is no limited thereto, and for example, the second trench t2 might not expose the second lower dielectric layer 320L.

The second sub-pad 382 defines the upper surface of the second lower dielectric layer 320L and the solder ball recess RC. The solder ball recess RC may expose the package substrate 300. The solder ball recess RC may expose the lower package substrate (300L in FIG. 2). The solder ball recess RC may expose the second lower dielectric layer 320L.

The second sub-pad 382 might not extend along the bottom surface of the second trench t2. The second sub-pad 382 may expend along the bottom surface of the first trench t1 and the sidewall of the second trench t2.

The first portion 392a of the second sub-solder ball 392 is disposed in the solder ball recess RC. At least a part of the first portion 392a of the second sub-solder ball 392 may be in contact with the second lower dielectric layer 320L.

Referring to FIG. 10, the second trench t2 may expose the package substrate 300. The second trench t2 may expose the lower package substrate (300L in FIG. 2). The second trench t2 might not expose the second lower dielectric layer 320L. However, the solder ball recess RC does not expose the package substrate 300. The solder ball recess RC does not expose the lower package substrate (300L in FIG. 2). The solder ball recess RC does not expose the second lower dielectric layer 320L.

The second sub-pad 382 may extend along the bottom surface of the first trench t1, the sidewall of the second trench t2, and the bottom surface of the second trench t2. At least a part of the second sub-pad 382 may be in contact with the second lower dielectric layer 320L.

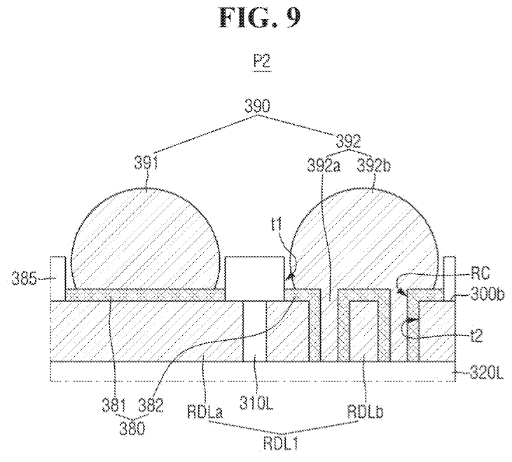

FIGS. 11 to 14 are enlarged views of a semiconductor package according to an exemplary embodiment of the present inventive concept. Various shapes of the second trench t2 in a plan view will be described with reference to FIGS. 11 to 14.

Referring to FIG. 11, the second trench t2 may have a circular shape in a plan view. The second trenches t2 may be formed at positions spaced apart from the center C of the first trench t1 by the same distance. Although it is illustrated that the second trenches t2 are spaced apart from each other by the same distance and have the same area as each other, the present inventive concept is not limited thereto. The arrangement, interval, size, and the like of the second trenches t2 may vary.

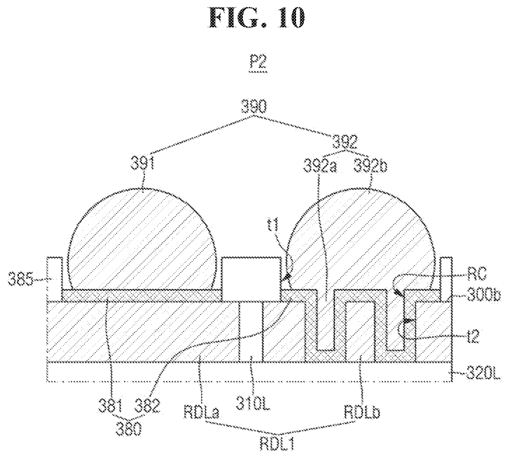

Referring to FIG. 12, the second trench t2 may be formed at a central region of the first trench t1. Six second trenches t2 may be formed at an edge region of the first trench t1 and one second trench t2 may be formed at the central region of the first trench t1.

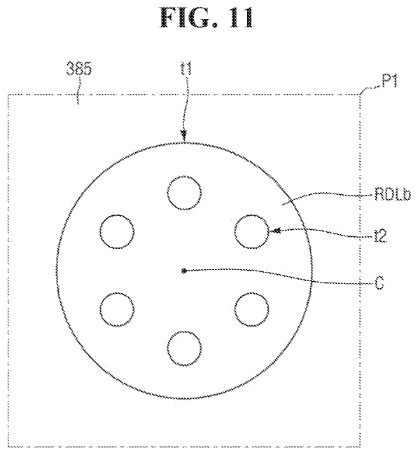

Referring to FIG. 13, the second trench t2 may have a square shape in a plan view. The second trenches t2 may be formed at positions spaced apart from the center C of the first trench t1 by the same distance. Although it is illustrated that the second trenches t2 are spaced apart from each other by the same distance and have the same area, the present inventive concept is not limited thereto. The arrangement, interval, size, and the like of the second trenches t2 may vary.

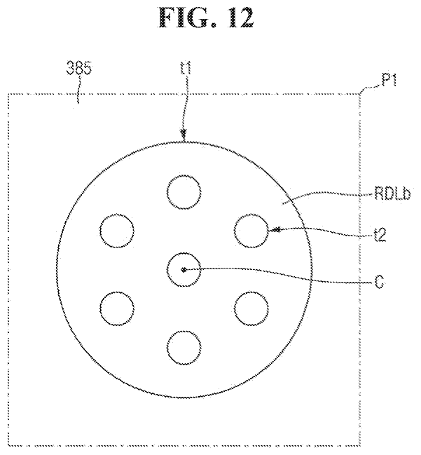

Referring to FIG. 14, the second trench t2 may have a rectangular shape in a plan view. Each of the second trenches t2 may have long sides and short sides. In an exemplary embodiment of the present inventive concept, long sides of the respective second trenches t2 may extend in different directions. For example, long sides of two trenches t2 may extend in a horizontal direction and long sides of other four second trenches t2 may extend in a direction at a predetermined angle with respect to the horizontal direction. However, the present inventive concept might not be limited thereto.

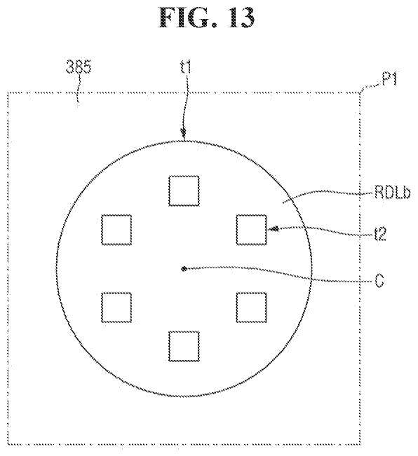

FIGS. 15 to 17 are cross-sectional views of a semiconductor package according to an exemplary embodiment of the present inventive concept. Hereinafter, various embodiments of the semiconductor package will be described. For convenience of explanation, a description will be given focusing on differences from those described with reference to FIGS. 1 to 4. For reference, FIGS. 15 to 17 may be cross-sectional views taken along line A-A of FIG. 1.

Referring to FIG. 15, unlike the embodiment shown in FIG. 2, a package substrate 300 may be formed on an active surface of a first semiconductor chip 100.

A lower package substrate 300L may be disposed directly on first chip pads 111 of the first semiconductor chip 100. The lower package substrate 300L may be in contact with the first chip pads 111 of the first semiconductor chip 100. First to fifth lower dielectric layers 310L, 320L, 330L, 340L, and 350L may be stacked on the first chip pads 111 of the first semiconductor chip 100. First to fourth redistribution patterns RDL1, RDL2, RDL3, and RDL4 may be disposed in the first to fifth lower dielectric layers 310L, 320L, 330L, 340L, and 350L.

For example, a via part of the first redistribution pattern RDL1 may be provided in the second lower dielectric layer 320L. A wiring part of the second redistribution pattern RDL2 may be provided in the second lower dielectric layer 320L. A via part of the second redistribution pattern RDL2 may be provided in the third lower dielectric layer 330L. A wiring part of the third redistribution pattern RDL3 may be provided in the third lower dielectric layer 330L. A via part of the third redistribution pattern RDL3 may be provided in the third lower dielectric layer 330L. The fourth redistribution pattern RDL4 may be provided in the fourth lower dielectric layer 340L.

In an exemplary embodiment of the present inventive concept, via parts of the fourth redistribution patterns RDL4 may be connected to the first chip pads 111 of the first semiconductor chip 100. The via parts of the fourth redistribution patterns RDL4 may be connected to metal pillars 360. In an exemplary embodiment of the present inventive concept, via parts of the first to fourth redistribution patterns RDL1, RDL2, RDL3, and RDL4 may be disposed on upper surfaces of wiring parts of the first to fourth redistribution patterns RDL1, RDL2, RDL3, and RDL4, respectively. For example, the via parts of the first to fourth redistribution patterns RDL1, RDL2, RDL3, and RDL4 may extend toward a first surface 300a from the upper surfaces of the respective wiring parts of the first to fourth redistribution patterns RDL1, RDL2, RDL3, and RDL4, respectively.

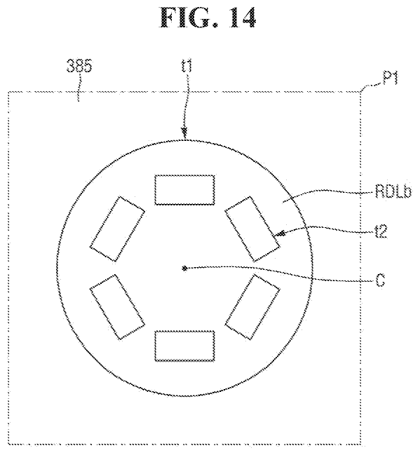

Referring to FIG. 16, a second semiconductor package 1000b may include two second semiconductor chips 200a and 200b. For example, the second semiconductor chips 200a and 200b may include a first sub-semiconductor chip 200a and a second sub-semiconductor chip 200b.

The first sub-semiconductor chip 200a and the second sub-semiconductor chip 200b may be spaced apart from each other. The first sub-semiconductor chip 200a and the second sub-semiconductor chip 200b may be separated from each other by an upper molding layer 430. Each of the first sub-semiconductor chip 200a and the second sub-semiconductor chip 200b may include second chip pads 221 at a lower surface thereof. The second semiconductor package 1000b does not include an upper conductive pad 403. In one example, second chip pads 221 may be electrically connected to lower conductive pads 405 through internal wiring lines 415 in a circuit board 410.

Although FIG. 16 illustrates that the first and second sub-semiconductor chips 200a and 200b are provided at the same level on an upper surface of the circuit board 410, the first sub-semiconductor chip 200a and the second sub-semiconductor chip 200b may be sequentially stacked on each other on the upper surface of the circuit board 410.

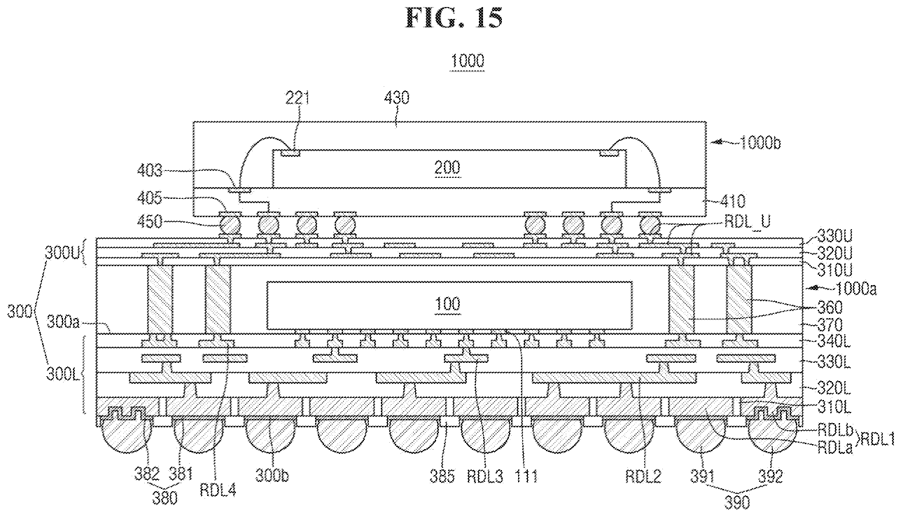

Referring to FIG. 17, unlike the embodiment shown in FIG. 2, the first semiconductor package 1000a may omit an upper package substrate.

For example, an upper dielectric layer 375 may be provided on a molding layer 370. The upper dielectric layer 375 may include a dielectric material. For example, the upper dielectric layer 375 may include at least one of silicon oxide, silicon nitride, silicon oxynitride, or a low-k dielectric material with a dielectric constant smaller than silicon oxide, but the present inventive concept is not limited thereto.

Second connection terminals 450 may be provided between the lower conductive pads 405 of the circuit board 410 and metal pillars 360 of the first semiconductor package 1000a. Some second connection terminals 450 may be disposed in the upper dielectric layer 375. One surfaces of the second connection terminals 450 may be connected to the lower conductive pads 405 and the other surfaces of the second connection terminals 450 may be connected to the metal pillars 360. Accordingly, the first semiconductor package 1000a and the second semiconductor package 1000b may be electrically connected to each other.

The second semiconductor chip 200 may be disposed on the circuit board 410. Second chip pads 221 of the second semiconductor chip 200 may be in contact with an upper surface of the circuit board 410. The second chip pads 221 of the second semiconductor chip 200 may be electrically connected to the lower conductive pads 405 through internal wiring lines 415 in the circuit substrate 410.

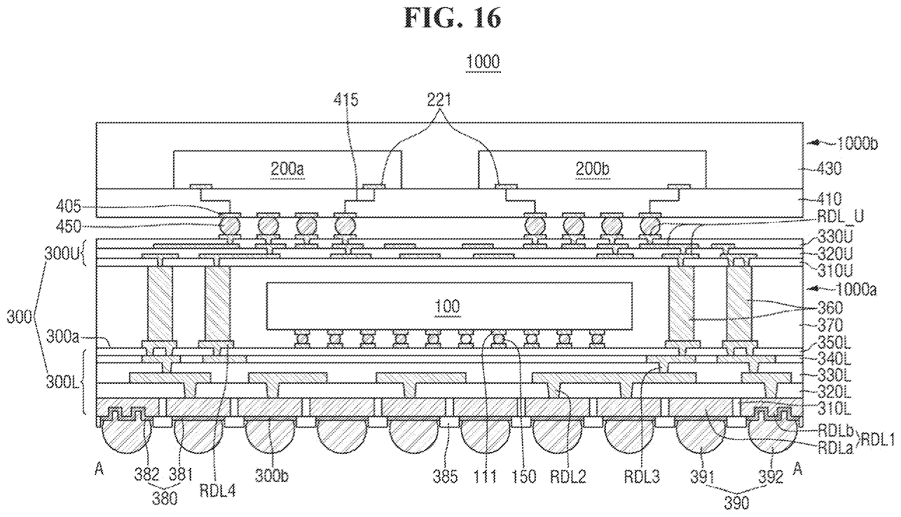

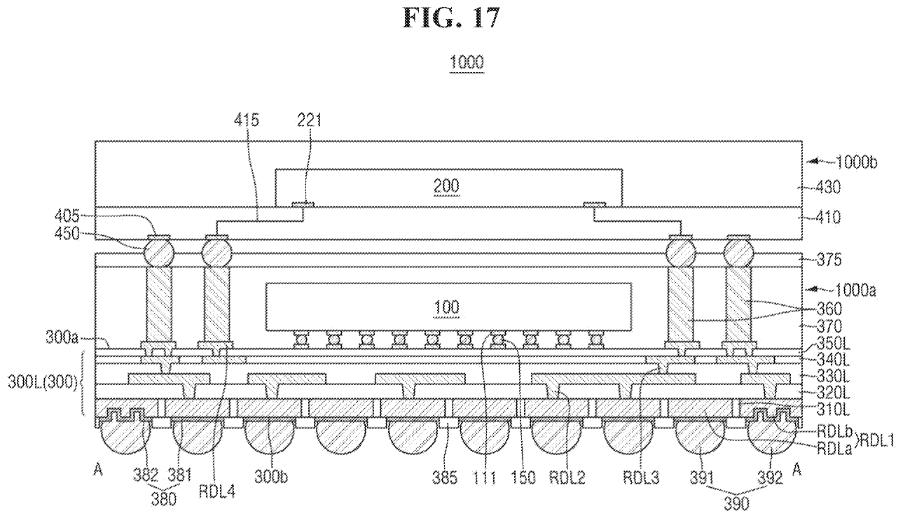

FIG. 18 is a plan view of a semiconductor package according to an exemplary embodiment of the present inventive concept. FIG. 19 is a cross-sectional view taken along line B-B of FIG. 18. Hereinafter, various embodiments of a semiconductor package will be described.

Referring to FIGS. 18 and 19, a semiconductor package 2000 according to an exemplary embodiment of the present inventive concept may include a package substrate 500, a first redistribution pattern RDL1, a pad 380, a solder ball 390, a solder resist layer 385, an interposer substrate 610, a third semiconductor chip 700a, and a fourth semiconductor chip 700b. The first redistribution pattern RDL1, the pad 380, the solder ball 390, and the solder resist layer 385 may be substantially the same as those described with reference to FIGS. 1 to 4, and thus detailed descriptions thereof will not be provided.

In FIG. 18, the package substrate 500 may include a first region R1 and a second region R2. The first region R1 may be a central region and the second region R2 may be an edge region. The second region R2 may have a step shape in a plan view.

The third semiconductor chip 700a and the fourth semiconductor chip 700b may be provided on the first region R1. The third semiconductor chip 700a and the fourth semiconductor chip 700b might not be provided on the second region R2.

In an exemplary embodiment of the present inventive concept, the third semiconductor chip 700a may be a logic semiconductor chip. For example, the first semiconductor chip 310 may be an application processor (AP), such as a central processing unit (CPU), a graphic processing unit (GPU), a field-programmable gate array (FPGA), a digital signal processor, an encryption processor, a micro-processor, a micro-controller, an application-specific IC, or the like, but the present inventive concept is not limited thereto.

In an exemplary embodiment of the present inventive concept, the fourth semiconductor chip 700b may be a memory semiconductor chip. For example, the fourth semiconductor chip 700b may be a volatile memory, such as a dynamic random access memory (DRAM) or a static random access memory (SRAM), or a non-volatile memory, such as a flash memory, a phase-change random access memory (PRAM), a magnetoresistive random access memory (MRAM), a ferroelectric random access memory (FeRAM), or a resistive random access memory (RRAM).

In one example, the first semiconductor chip 700a may be ASIC such as GPU, and the second semiconductor chip 700b may be a stack memory such as high bandwidth memory (HBM). The stack memory may have a plurality of integrated circuits stacked therein. The stacked integrated circuits may be electrically connected to one another through a through silicon via (TSV) or the like.

The package substrate 500 may be a substrate for a package. For example, the package substrate 500 may be a PCB. The package substrate 500 may include a lower surface and an upper surface opposed to the lower surface. The upper surface of the package substrate 500 may face the interposer substrate 610.

The package substrate 500 may include a substrate pad 504. The substrate pad 504 may be used to electrically connect the package substrate 500 to other components. For example, the substrate pad 504 may be exposed from the upper surface of the package substrate 500. The substrate pad 504 may electrically connect a first redistribution pattern RDL1 to a third connection terminal 650 through an internal wiring line 505 in the package substrate 500. The substrate pad 504 may include, for example, a metal material such as copper (Cu), aluminum (Al), or the like, but the present inventive concept is not limited thereto.

In an exemplary embodiment of the present inventive concept, the package substrate 500 may include a copper clad laminate (CCL). For example, the package substrate 500 may have a structure in which a copper laminate is stacked on one side or both sides of a thermosetting pre-preg (for example, pre-preg of a C-Stage).

The interposer substrate 610 may be disposed on the upper surface of the package substrate 500. The interposer substrate 610 may include a lower surface and an upper surface opposed to the lower surface. The upper surface of the interposer substrate 610 may face the third and fourth semiconductor chips 700a and 700b. The lower surface of the interposer substrate 610 may face the package substrate 500. The interposer substrate 610 may facilitate the connection between the package substrate 500 and the third and fourth semiconductor chips 700a and 700b, and may prevent and/or mitigate warpage of the semiconductor package 2000. The interposer substrate 610 may be, for example, a silicon (Si) interposer, but the present inventive concept is not limited thereto.

The semiconductor package 2000 according to an exemplary embodiment of the present inventive concept may include an interlayer dielectric layer 620, a first passivation film 630, a second passivation film 635, wiring patterns 640, through vias 645, first interposer pads 602, and second interposer pads 604.

The interlayer dielectric layer 620 may be disposed on the interposer substrate 610. The interlayer dielectric layer 620 may include a dielectric material. For example, the interlayer dielectric layer 620 may include at least one of silicon oxide, silicon nitride, silicon oxynitride, and/or a low-k dielectric material with a dielectric constant smaller than that of silicon oxide, but the present inventive concept is not limited thereto.

The first interposer pads 602 and the second interposer pads 604 may each be used for electrical connections to other components. For example, the first interposer pads 602 may be exposed from the lower surface of the interposer substrate 610, and the second interposer pads 604 may be exposed from an upper surface of the interlayer dielectric layer 620. The first interposer pads 602 and the second interposer pads 604 may include, for example, a metal material such as copper (Cu), aluminum (Al), or the like, but the present inventive concept is not limited thereto. Wiring patterns for electrically connecting the first interposer pads 602 to the second interposer pads 604 may be formed in the interposer substrate 610 and the interlayer dielectric layer 620.

For example, the through vias 645 may be formed in the interposer substrate 610. The wiring patterns 640 may be formed in the interlayer dielectric layer 620. The through vias 645 may penetrate through the interposer substrate 610. The wiring patterns 640 and the through vias 645 may be connected to each other. The wiring patterns 640 may be electrically connected to the second interposer pads 604. The through via 645 may be electrically connected to the first interposer pad 602. Accordingly, the package substrate 500 may be electrically connected to the third semiconductor chip 700a and the fourth semiconductor chip 700b. Redistribution layers 240 and the through vias 245 may each include a metal material such as copper (Cu), aluminum (Al), or the like, but the present inventive concept is not limited thereto.

A third connection terminal 650 may be formed between the package substrate 500 and the interposer substrate 610. The third connection terminal 650 may connect the substrate pad 504 to the first interposer pad 602. Accordingly, the package substrate 500 and the interposer substrate 610 may be electrically connected to each other.

The third connection terminal 650 may be, for example, but the present inventive concept is not limited to, a solder bump. The solder bump may include, for example, a metal (e.g., tin (Sn)) and/or a Sn alloy with a low-melting point. The third connection terminal 650 may have various shapes, such as a land, a ball, a pin, and/or a pillar. The third connection terminal 650 may be formed of a single layer or multi-layers. When the third connection terminal 650 is formed of a single layer, the third connection terminals 650 may include, for example, tin-silver (Sn—Ag) solder and/or copper (Cu). When the third connection terminal 650 is formed of multi-layers, the third connection terminal 650 may include, for example, a copper filler and solder. The number, interval, arrangement form, and the like of the third connection terminal 650 are not limited to those shown, and may, of course, be various.

The first passivation film 630 may be disposed on the interlayer dielectric layer 620. The first passivation film 630 may be elongated along the upper surface of the interlayer dielectric layer 620. The second interposer pads 604 may penetrate through the first passivation film 630 and be connected to the wiring patterns 640. The second passivation film 635 may be disposed on the interposer substrate 610. The second passivation film 635 may be elongated along the lower surface of the interposer substrate 610. The first interposer pad 602 may penetrate through the second passivation film 635 and be connected to the through via 645.

The first passivation film 630 and the second passivation film 635 may each include, for example, silicon nitride. In addition, each of the first passivation film 630 and the second passivation film 635 may include, for example, a passivation material, benzocyclobutene (BCB), polybenzeneoxazole, polyimide, epoxy, silicon oxide, silicon nitride, or a combination thereof.

In an exemplary embodiment of the present inventive concept, a first underfill 660 may be formed between the package substrate 500 and the interposer substrate 610. The first underfill 660 may fill a space between the package substrate 500 and the interposer substrate 610. In addition, the first underfill 660 may cover the third connection terminal 650. The first underfill 660 may prevent and/or mitigate breakage or the like of the interposer substrate 610 by fixing the interposer substrate 610 onto the package substrate 500. The first underfill 660 may include, but is not limited to, an insulating polymeric material such as an epoxy-molding compound (EMC).

The third semiconductor chip 700a and the fourth semiconductor chip 700b may be placed on the upper surface of the interposer substrate 610 and may be spaced apart from each other. Each of the third semiconductor chip 700a and the fourth semiconductor chip 700b may be an integrated circuit (IC) in which hundreds to millions or more semiconductor elements are integrated in a single chip.

The third semiconductor chip 700a may include third chip pads 712. The third chip pads 712 may be used to electrically connect the third semiconductor chip 700a to other components. For example, the third chip pads 712 may be exposed from the lower surface of the third semiconductor chip 700a.

The fourth semiconductor chip 700b may include fourth chip pads 714. The fourth chip pads 714 may be used to electrically connect the fourth semiconductor chip 700b to other components. For example, the fourth chip pads 714 may be exposed from the lower surface of the fourth semiconductor chip 700b.

Each of the third chip pads 712 and the fourth chip pads 714 may include, for example, a metal material such as copper (Cu), aluminum (Al), or the like, but the present inventive concept is not limited thereto.

The third semiconductor chip 700a and the fourth semiconductor chip 700b may be mounted onto the upper surface of the interlayer dielectric layer 620. For example, fourth connection terminals 752 may be formed between the interlayer dielectric layer 620 and the third semiconductor chip 700a. The fourth connection terminals 752 may connect some of the plurality of second interposer pads 604 to the third chip pads 712. Accordingly, the interposer substrate 610 and the third semiconductor chip 700a may be electrically connected to each other.

In addition, for example, fifth connection terminals 754 may be formed between the interlayer dielectric layer 620 and the fourth semiconductor chip 700b. The fifth connection terminals 754 may connect some others of the plurality of second interposer pads 604 to the fourth chip pads 714. Accordingly, the interposer substrate 610 and the fourth semiconductor chip 700b may be electrically connected to each other.

Each of the fourth connection terminals 752 and the fifth connection terminals 754 may be, for example, but is not limited to, a solder bump. The solder bump may include, for example, a metal (e.g., tin (Sn)) and/or a Sn alloy with a low-melting point. Each of the fourth connection terminals 752 and the fifth connection terminals 754 may have various shapes, such as a land, a ball, a pin, and/or a pillar. In addition, each of the fourth connection terminals 752 and the fifth connection terminals 754 may include under bump metallurgy (UBM).

Each of the fourth connection terminals 752 and the fifth connection terminals 754 may be formed of a single layer or multi-layers. When each of the fourth connection terminals 752 and the fifth connection terminals 754 is formed of a single layer, the fourth connection terminals 752 and the fifth connection terminals 754 may each include, for example, tin-silver (Sn—Ag) solder and/or copper (Cu). When each of the fourth connection terminals 752 and the fifth connection terminals 754 is formed of multi-layers, the fourth connection terminals 752 and the fifth connection terminals 754 may each include, for example, a copper filler and solder. However, the present inventive concept is not limited thereto. The number, interval, arrangement form, and the like of the fourth connection terminals 752 and the fifth connection terminals 754 are not limited to those shown, and may, of course, be various.

In an exemplary embodiment of the present inventive concept, some wiring patterns 640 may electrically connect the fourth connection terminal 752 to the fifth connection terminal 754. For example, some wiring patterns 640 may be connected to the second interposer pad 604 to which the fourth connection terminal 752 is connected, and may be connected to the second interposer pad 604 to which the fifth connection terminal 754 is connected. Accordingly, the third semiconductor chip 700a and the second semiconductor chip 700b may be electrically connected to each other.

In an exemplary embodiment of the present inventive concept, a second underfill 762 may be formed between the interlayer dielectric layer 620 and the third semiconductor chip 700a. A third underfill 764 may be formed between the interlayer dielectric layer 620 and the fourth semiconductor chip 700b. The second underfill 762 may fill a space between the interlayer dielectric layer 620 and the third semiconductor chip 700a. The third underfill 764 may fill a space between the interlayer dielectric layer 620 and the fourth semiconductor chip 700b. In addition, the second underfill 762 may cover the fourth connection terminals 752. The third underfill 764 may cover the fifth connection terminals 754.

The second underfill 762 and the third underfill 764 may prevent and/or mitigate breakage or the like of the third and fourth semiconductor chips 700a and 700b by fixing the third and fourth semiconductor chips 700a and 700b onto the interposer substrate 610. Each of the second underfill 762 and the third underfill 764 may include, but is not limited to, an insulating polymeric material such as an EMC.

A mold layer 800 may be disposed on the interposer substrate 610. The mold layer 800 may be provided between the third semiconductor chip 700a and the fourth semiconductor chip 700b. The mold layer 800 may separate the third semiconductor chip 700a from the fourth semiconductor chip 700b.

The mold layer 800 may include, but is not limited to, an insulating polymeric material such as an EMC. The mold layer 800 may include a different material from those of the first underfill 660, the second underfill 762, and the third underfill 764. For example, each of the first underfill 660, the second underfill 762, and the third underfill 764 may include a dielectric material having fluidity superior to that of the mold layer 800. Accordingly, the first underfill 660, the second underfill 762, and the third underfill 764 may efficiently fill a narrow space between the package substrate 500 and the interposer substrate 610, or between the interlayer dielectric layer 620 and the third and fourth semiconductor chips 700a and 700b.

The semiconductor package 2000 according to an exemplary embodiment of the present inventive concept may further include an adhesive layer 850 and a heat slug 900.

The adhesive layer 850 may be provided on the mold layer 800. The adhesive layer 850 may be provided on the third semiconductor chip 700a and the fourth semiconductor chip 700b. For example, the adhesive layer 850 may be in contact with an upper surface of the mold layer 800. For example, the adhesive layer 850 may be in contact with the upper surface of the third semiconductor chip 700a and the upper surface of the fourth semiconductor chip 700b. The adhesive layer 850 may adhere and fix the mold layer 800, the third semiconductor chip 700a, and the fourth semiconductor chip 700b to the heat slug 900. The adhesive layer 850 may include an adhesive material. For example, the adhesive layer 850 may include a curable polymer. The adhesive layer 850 may include, for example, an epoxy-based polymer.

The heat slug 900 may be disposed on the package substrate 500. The heat slug 900 may cover the third semiconductor chip 700a and the fourth semiconductor chip 700b. The heat slug 900 may include a metal material, but is not limited thereto.

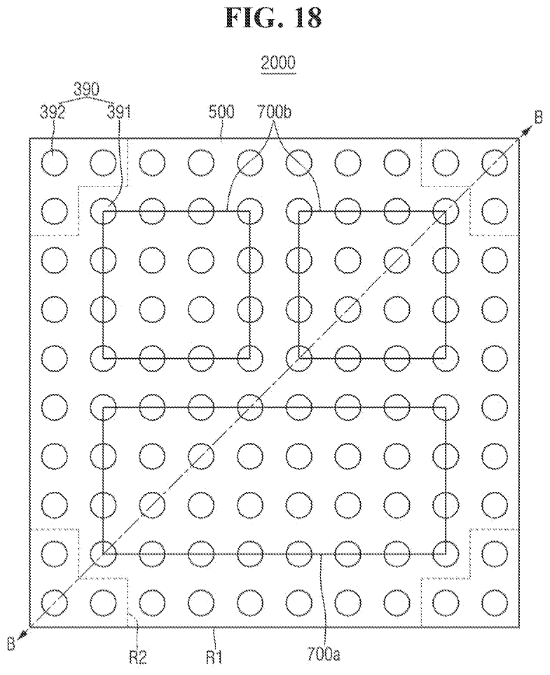

Hereinafter, a method of manufacturing a semiconductor package according to an exemplary embodiment of the present inventive concept will be described with reference to FIGS. 20 to 24.

FIGS. 20 to 24 are views illustrating intermediate stages of a method of manufacturing a semiconductor package according to an exemplary embodiment of the present inventive concept. For reference, FIGS. 20 to 24 are views illustrating a method of forming a pad 380, a first redistribution pattern RDL1, a solder resist layer 385, and a solder ball 390 of a semiconductor package.

Referring to FIG. 20, a first lower dielectric layer 310L, a first sub-redistribution pattern RDLa, and a pre second sub-redistribution pattern RDLb_p may be formed on a second lower dielectric layer 320L. The pre second sub-redistribution pattern RDLb_p may include, for example, copper (Cu), but is not limited thereto.

The first lower dielectric layer 310L and the second lower dielectric layer 320L may be constituent parts of a package substrate. The first lower dielectric layer 310L may be provided between the first sub-redistribution pattern RDLa and the pre second sub-redistribution pattern RDLb_p.

A pre solder resist layer 385P may be formed on the first lower dielectric layer 310L, the first sub-redistribution pattern RDLa, and the pre second sub-redistribution pattern RDLb_p. The pre solder resist layer 385P may cover the first lower dielectric layer 310L, the first sub-redistribution pattern RDLa, and the pre second sub-redistribution pattern RDLb_p. The pre solder resist layer 385P may include, for example, a silver solder resist material.

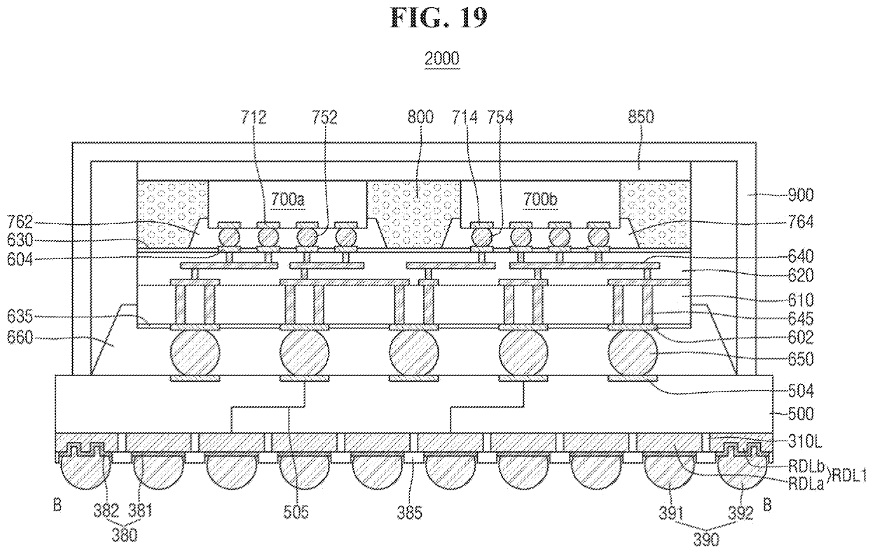

Referring to FIG. 21, a first trench t1 may be formed. The first trench t1 may be formed by etching the pre solder resist layer 385P. The solder resist layer 385 may be formed by etching the pre solder resist layer 385P. The solder resist layer 385 may include the first trench t1.

The first trench t1 may expose the first sub-redistribution pattern RDLa. The first trench t1 may expose the pre second sub-redistribution pattern RDLb_p. The first trench t1 might not expose the first lower dielectric layer 310L.

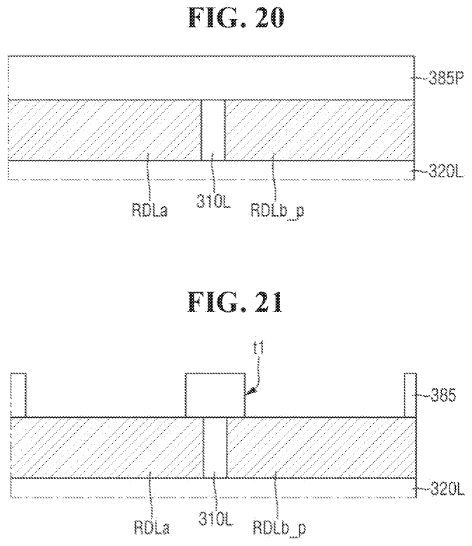

Referring to FIG. 22, a second trench t2 may be formed. The second trench t2 may be formed by etching the pre second sub-redistribution pattern RDLb_p. A second sub-redistribution pattern RDLb may be formed by etching the pre second sub-redistribution pattern RDLb_p. The first sub-redistribution pattern RDLa and the second sub-redistribution pattern RDLb may constitute the first redistribution pattern RDL1.

The second sub-redistribution pattern RDLb may include the second trench t2. The second trench t2 does not expose the package substrate. The second trench t2 does not expose the second lower dielectric layer 320L. However, the present inventive concept might not be limited thereto. According to an exemplary embodiment of the present inventive concept, the second trench t2 may expose the package substrate.

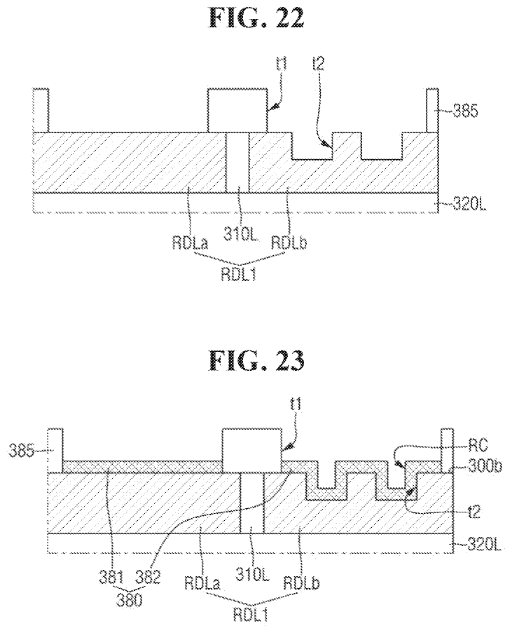

Referring to FIG. 23, the pad 380 may be formed. The pad 380 may include a first sub-pad 381 and a second sub-pad 382.

The first sub-pad 381 may be formed along the bottom surface of the first trench t1. The first sub-pad 381 may be formed on the first sub-redistribution pattern RDLa. The second sub-pad 382 may be formed along the bottom surface of the first trench t1, the sidewall of the second trench t2, and the bottom surface of the second trench t2. The second sub-pad 382 may be formed on the second sub-redistribution pattern RDLb. The second sub-pad 382 may provide a solder ball recess RC. The first sub-pad 381 and the second sub-pad 382 may each include, for example, NiAu.

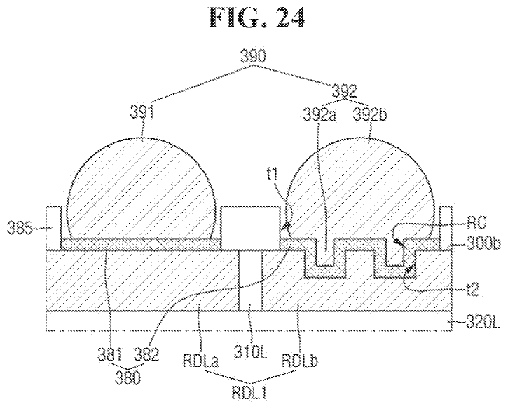

Referring to FIG. 24, the solder ball 390 may be formed. The solder ball 390 may include a first sub-solder ball 391 and a second sub-solder ball 392. The first sub-solder ball 391 may be formed on the first sub-pad 381. The second sub-solder ball 392 may be formed on the second sub-pad 382.

In an exemplary embodiment of the present inventive concept, the second sub-solder ball 392 may include a first portion 392a and a second portion 392b. The first portion 392a may be disposed within the solder ball recess RC. The second portion 392b may be disposed on the first portion 392a.

The semiconductor package according to an exemplary embodiment of the present inventive concept has a structure in which the solder ball recess RC is included and a portion of the second sub-solder ball 392 is disposed in the solder ball recess RC, so that a semiconductor package with increased reliability may be provided. For example, the contact area between the second sub-solder ball 392 and the second sub-pad 382 may be increased. Accordingly, when a crack is generated, the crack may be prevented from further developing, or a crack may be prevented from being generated.

While the present inventive concept has been described with reference to exemplary embodiments thereof, it will be understood by those of ordinary skill in the art that various changes in form and details may be made thereto without departing from the spirit and scope of the present inventive concept.

What is claimed:

1. A semiconductor package comprising:
a package substrate including a first region and a second region excluding the first region, wherein the package substrate includes a first surface and a second surface that are opposed to each other;
a semiconductor chip mounted on the first surface of the package substrate;
a pad including a first sub-pad and a second sub-pad, wherein the first sub-pad is disposed on the second surface of the first region of the package substrate, and the second sub-pad is disposed on the second surface of the second region of the package substrate and includes a solder ball recess; and
a solder ball disposed on the second surface, wherein the solder ball includes a first sub-solder ball and a second sub-solder ball, wherein the first sub-solder ball is connected to the first sub-pad, and the second sub-solder ball is connected to the second sub-pad,
wherein the second sub-solder ball includes a first portion and a second portion, wherein the first portion is disposed in the solder ball recess, and the second portion is disposed on the first portion.

2. The semiconductor package of claim 1, wherein the second region is adjacent to an edge area of the package substrate and has a step shape in a plan view.

3. The semiconductor package of claim 1, wherein at least a part of the second region overlaps the semiconductor chip in a thickness direction of the package substrate.

4. The semiconductor package of claim 1, wherein the solder ball recess exposes the package substrate.

5. The semiconductor package of claim 1, further comprising a redistribution pattern connected to the second sub-pad,
wherein the first portion of the second sub-solder ball overlaps the redistribution pattern, and the second portion of the second sub-solder ball is not disposed in the redistribution pattern.

6. The semiconductor package of claim 1, wherein a thickness of the second sub-pad is not constant.

7. The semiconductor package of claim 1, wherein a thickness of the second sub-pad is constant.

8. The semiconductor package of claim 1, wherein an upper surface of the first sub-pad is flat.

9. The semiconductor package of claim 1, wherein the pad includes NiAu.

10. The semiconductor package of claim 1, wherein the first sub-solder ball does not overlap the first portion of the second sub-solder ball in a direction that is perpendicular to a thickness direction of the package substrate.

11. The semiconductor package of claim 1, wherein the semiconductor chip does not overlap the second region in a thickness direction of the package substrate.

12. A semiconductor package comprising:
a package substrate including an edge region and a central region excluding the edge region, wherein the package substrate includes a first surface and a second surface that are opposed to each other;
a semiconductor chip mounted on the central region of the package substrate;
a first sub-redistribution pattern disposed at the central region of the package substrate;
a second sub-redistribution pattern disposed at the edge region of the package substrate and including a trench;
a first sub-pad disposed on the second surface of the package substrate and connected to the first sub-redistribution pattern;
a second sub-pad disposed on the second surface of the package substrate and connected to the second sub-redistribution pattern;
a first sub-solder ball connected to the first sub-pad; and
a second sub-solder ball connected to the second sub-pad,
wherein the second sub-pad extends along a sidewall and a bottom surface of the trench,
wherein at least a part of the second sub-solder ball is disposed on second sub-pad in the trench,
wherein the at least a part of the second sub-solder ball overlaps the second sub-redistribution pattern in a direction that is perpendicular to a thickness direction of the package substrate, and
wherein an upper surface of the first sub-pad is flat.

13. The semiconductor package of claim 12, wherein the trench exposes the package substrate.

14. The semiconductor package of claim 12, wherein each of the first sub-pad and the second sub-pad includes NiAu.

15. The semiconductor package of claim 12, wherein the trench has at least one of a circular shape, a square shape, a rectangular shape, or a fan shape.

16. The semiconductor package of claim 12, wherein the first sub-solder ball does not overlap the first sub-redistribution pattern in the direction that is perpendicular to the thickness direction of the package substrate.

17. The semiconductor package of claim 12, wherein the edge region has a step shape.

18. A semiconductor package comprising:
a package substrate including four edge regions and a central region excluding the edge regions, wherein the package substrate includes a first surface and a second surface that are opposed to each other, wherein each of the four edge regions having a step shape;
at least one semiconductor chip mounted on the first surface of the central region of the package substrate;
a solder resist layer disposed on the second surface and including a first trench;
a redistribution pattern including a first sub-redistribution pattern and a second sub-redistribution pattern, wherein the first sub-redistribution pattern is disposed at the central region of the package substrate, and the second sub-redistribution pattern is disposed at the edge region of the package substrate and includes a plurality of second trenches;
a first sub-pad extending along a bottom surface of the first trench and being connected to the first sub-redistribution pattern;
a second sub-pad extending along the bottom surface of the first trench and a sidewall and a bottom surface of the second trench and being connected to the second sub-redistribution pattern;
a first sub-solder ball connected to the first sub-pad; and
a second sub-solder ball connected to the second sub-pad,
wherein the first trench exposes the redistribution pattern,
wherein the plurality of second trenches do not expose the package substrate,
wherein the second sub-solder ball includes a first portion and a second portion, wherein the first portion fills the second trenches, and the second portion is disposed on the first portion,
wherein the first portion of the second sub-solder ball does not overlap the first sub-solder ball in a direction that is perpendicular to a thickness direction of the package substrate, and
wherein each of the first sub-pad and the second sub-pad includes NiAu.

19. The semiconductor package of claim 18, wherein an upper surface of the first sub-pad is flat.

20. The semiconductor package of claim 18, wherein the second trenches are not formed in a central region of the first trench.
